(19) United States
(12) Patent Application Publication
(10) Pub. No.: US 2007/0131270 A1
(43) Pub. Date: Jun. 14, 2007

(54) Window with photovoltaic cell

(76) Inventors: Russell Gaudiana, Merrimack, NH (US); Richard Kingsborough, North Chelmsford, MA (US); Daniel Patrick McGahn, Boston, MA (US); Xiaobo Shi, Manchester, NH (US); David Waller, Lexington, MA (US); Zhengguo Zhu, Chelmsford, MA (US)

Correspondence Address: FISH & RICHARDSON PC, P.O. BOX 1022, MINNEAPOLIS, MN, 55440-1022, US

(21) Appl. No.: 11/601,374

(22) Filed: Nov. 17, 2006

Related U.S. Application Data
(63) Continuation-in-part of application No. 11/486,536, filed on Jul. 14, 2006.
Application No. 11/486,536 is a continuation-in-part of application No. 11/450,521, filed on Jun. 9, 2006.
Application No. 11/450,521 is a continuation-in-part of application No. 11/375,643, filed on Mar. 14, 2006.
(60) Provisional application No. 60/699,123, filed on Jul. 14, 2005.
(60) Provisional application No. 60/850,963, filed on Oct. 11, 2006.
(60) Provisional application No. 60/850,845, filed on Oct. 11, 2006.
(60) Provisional application No. 60/738,270, filed on Nov. 18, 2005.

(51) Int. Cl. H02N 6/00; H01L 31/00

(52) U.S. Cl. 136/244; 136/252

(57) ABSTRACT

Windows with photovoltaic cells, as well as related systems, methods and components are disclosed.

### CROSS REFERENCE TO RELATED APPLICATIONS

This application is a continuation-in-part of U.S. Utility application Ser. No.: 11/486,536, filed Jul. 14, 2006, which in turn is a continuation-in-part of U.S. Utility application Ser. No.: 11/450,521, filed Jun. 9, 2006, which in turn is a continuation-in-part of U.S. Utility application Ser. No.: 11/375,643, filed Mar. 14, 2006, which claims priority to U.S. Provisional Application Ser. No. 60/699,123, filed Jul. 14, 2005. This application is also a continuation-in-part of U.S. Utility application Ser. No.: 11/485,708, filed Jul. 13, 2006. Finally, this application also claims priority to U.S. Provisional Application Ser. No. 60/850,963, filed Oct. 11, 2006, U.S. Provisional Application Ser. No. 60/850,845, filed Oct. 11, 2006, and U.S. Provisional Application Ser. No. 60/738,270, filed Nov. 18, 2005. The contents of all parent applications are hereby incorporated by reference.

### TECHNICAL FIELD

This invention relates to windows with photovoltaic cells, as well as related components, systems, and methods.

### BACKGROUND

Photovoltaic cells are commonly used to transfer energy in the form of light into energy in the form of electricity. A typical photovoltaic cell includes a photoactive material disposed between two electrodes. Generally, light passes through one or both of the electrodes to interact with the photoactive material. As a result, the ability of one or both of the electrodes to transmit light (e.g., light at one or more wavelengths absorbed by a photoactive material) can limit the overall efficiency of a photovoltaic cell. In many photovoltaic cells, a film of semiconductive material (e.g., indium tin oxide) is used to form the electrode(s) through which light passes because, although the semiconductive material can have a lower electrical conductivity than electrically conductive materials, the semiconductive material can transmit more light than many electrically conductive materials.

### SUMMARY

This invention relates to windows with photovoltaic cells, as well as related components, systems, and methods.

In one aspect, the invention features an article that includes first and second window panes; and a photovoltaic cell between the first and second window panes.

In another aspect, the invention features an article that includes a window blind and a photovoltaic cell on a surface of a window blind.

Embodiments can include one or more of the following features.

The photovoltaic cell can include a first electrode, a second electrode, and an photoactive material disposed between the first and second electrodes, the photoactive material comprising a polymer including a first comonomer repeat unit and a second comonomer repeat unit different from the first comonomer repeat unit, the first comonomer repeat unit comprising a cyclopentadithiophene moiety, a silacyclopentadithiophene moiety, a cyclopentadithiazole moiety, a thiazolothiazole moiety, or a thiazole moiety.

The first comonomer repeat unit can include a cyclopentadithiophene moiety. In some embodiments, the cyclopentadithiophene moiety is substituted with at least one substituent selected from the group consisting of C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. For example, the cyclopentadithiophene moiety can be substituted with hexyl, 2-ethylhexyl, or 3,7-dimethyloctyl. In certain embodiments, the cyclopentadithiophene moiety is substituted at 4-position. In certain embodiments, the first comonomer repeat unit can include a cyclopentadithiophene moiety of formula (1): 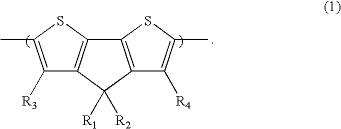
In formula (1), each of H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. For example, each of R₁ and R₂, independently, can be hexyl, 2-ethylhexyl, or 3,7-dimethyloctyl.

The second comonomer repeat unit can include a benzothiadiazole moiety, a thiadiazoloquinoxaline moiety, a cyclopentadithiophene oxide moiety, a benzoisothiazole moiety, a benzothiazole moiety, a thiophene oxide moiety, a thienothiophene moiety, a thienothiophene oxide moiety, a dithienothiophene moiety, a dithienothiophene oxide moiety, a tetrahydroisoindole moiety, a fluorene moiety, a silole moiety, a cyclopentadithiophene moiety, a fluorenone moiety, a thiazole moiety, a selenophene moiety, a thiazolothiazole moiety, a cyclopentadithiazole moiety, a naphthothiadiazole moiety, a thienopyrazine moiety, a silacyclopentadithiophene moiety, an oxazole moiety, an imidazole moiety, a pyrimidine moiety, a benzoxazole moiety, or a benzimidazole moiety. In some embodiments, the second comonomer repeat unit is a 3,4-benzo-1,2,5-thiadiazole moiety.

The second comonomer repeat unit can include a benzothiadiazole moiety of formula (2), a thiadiazoloquinoxaline moiety of formula (3), a cyclopentadithiophene dioxide moiety of formula (4), a cyclopentadithiophene monoxide moiety of formula (5), a benzoisothiazole moiety of formula (6), a benzothiazole moiety of formula (7), a thiophene dioxide moiety of formula (8), a cyclopentadithiophene dioxide moiety of formula (9), a cyclopentadithiophene tetraoxide moiety of formula (10), a thienothiophene moiety of formula (11), a thienothiophene tetraoxide moiety of formula (12), a dithienothiophene moiety of formula (13), a dithienothiophene dioxide moiety of formula (14), a dithienothiophene tetraoxide moiety of formula (15), a tetrahydroisoindole moiety of formula (16), a thienothiophene dioxide moiety of formula (17), a dithienothiophene dioxide moiety of formula (18), a fluorene moiety of formula (19), a silole moiety of formula (20), a cyclopentadithiophene moiety of formula (21), a fluorenone moiety of formula (22), a thiazole moiety of formula (23), a selenophene moiety of formula (24), a thiazolothiazole moiety of formula (25), a cyclopentadithiazole moiety of formula (26), a naphthothiadiazole moiety of formula (27), a thienopyrazine moiety of formula (28), a silacyclopentadithiophene moiety of formula (29), an oxazole moiety of formula (30), an imidazole moiety of formula (31), a pyrimidine moiety of formula (32), a benzoxazole moiety of formula (33), or a benzimidazole moiety of formula (34):

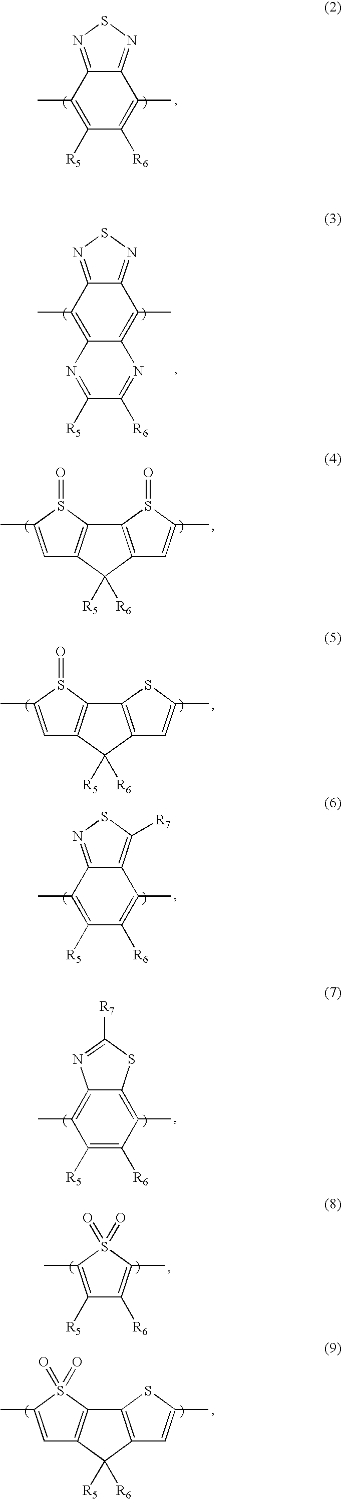

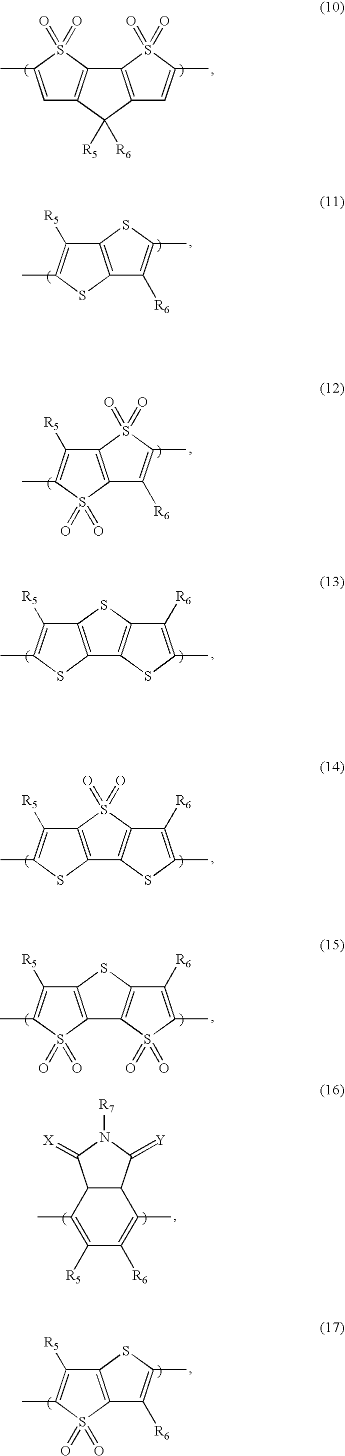

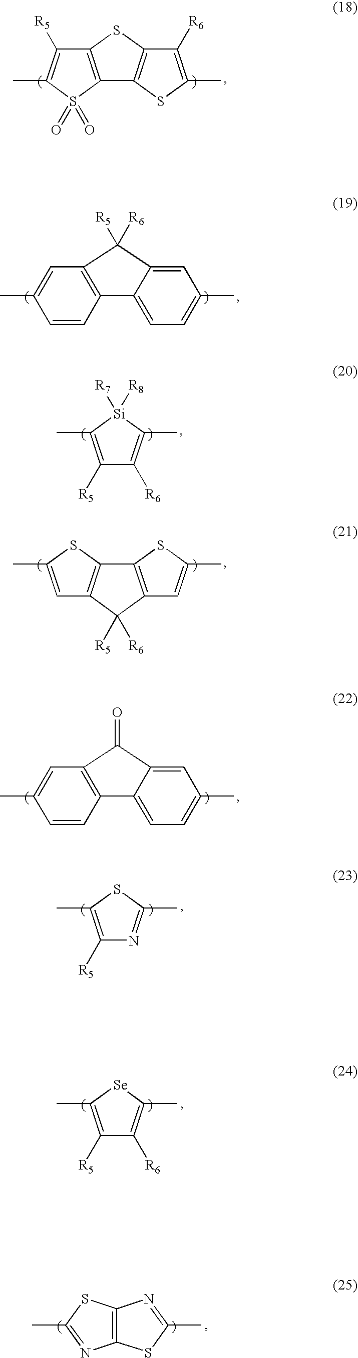

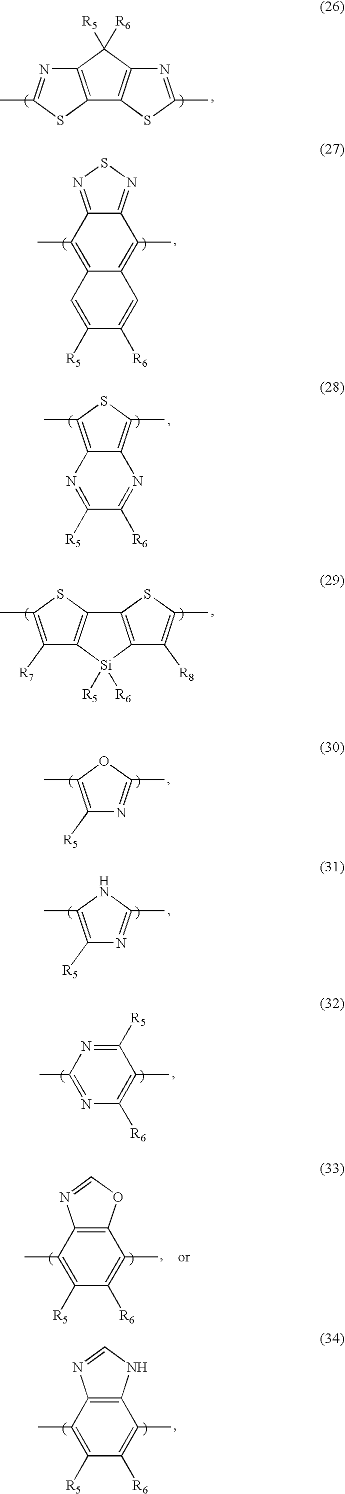

In the above formulas, each of X and Y, independently, is CH₂, O, or S; each of R₅ and R₆, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R, in which R is H, C₁-C₂₀ alkyl, C₁-C₂₀ alkoxy, aryl, heteroaryl, C₃-C₂₀ cycloalkyl, or C₁-C₂₀ heterocycloalkyl; and each of R₇ and R₈, independently, is H, C₁-C₂₀ alkyl, C₁-C₂₀ alkoxy, aryl, heteroaryl, C₃-C₂₀ cycloalkyl, or C₃-C₂₀ heterocycloalkyl. In some embodiments, the second comonomer repeat unit includes a benzothiadiazole moiety of formula (2), in which each of R₅ and R6 is H.

The second comonomer repeat unit can include at least three thiophene moieties. In some embodiments, at least one of the thiophene moieties is substituted with at least one substituent selected from the group consisting of C₁-C₂₀ alkyl, C₁-C₂₀ alkoxy, aryl, heteroaryl, C₃-C₂₀ cycloalkyl, and C₃-C₂₀ heterocycloalkyl. In certain embodiments, the second comonomer repeat unit includes five thiophene moieties.

The polymer can further include a third comonomer repeat unit that contains a thiophene moiety or a fluorene moiety. In some embodiments, the thiophene or fluorene moiety is substituted with at least one substituent selected from the group consisting of C₁-C₂₀ alkyl, C₁-C₂₀ alkoxy, aryl, heteroaryl, C₃-C₂₀ cycloalkyl, and C₃-C₂₀ heterocycloalkyl.

In some embodiments, the polymer can be 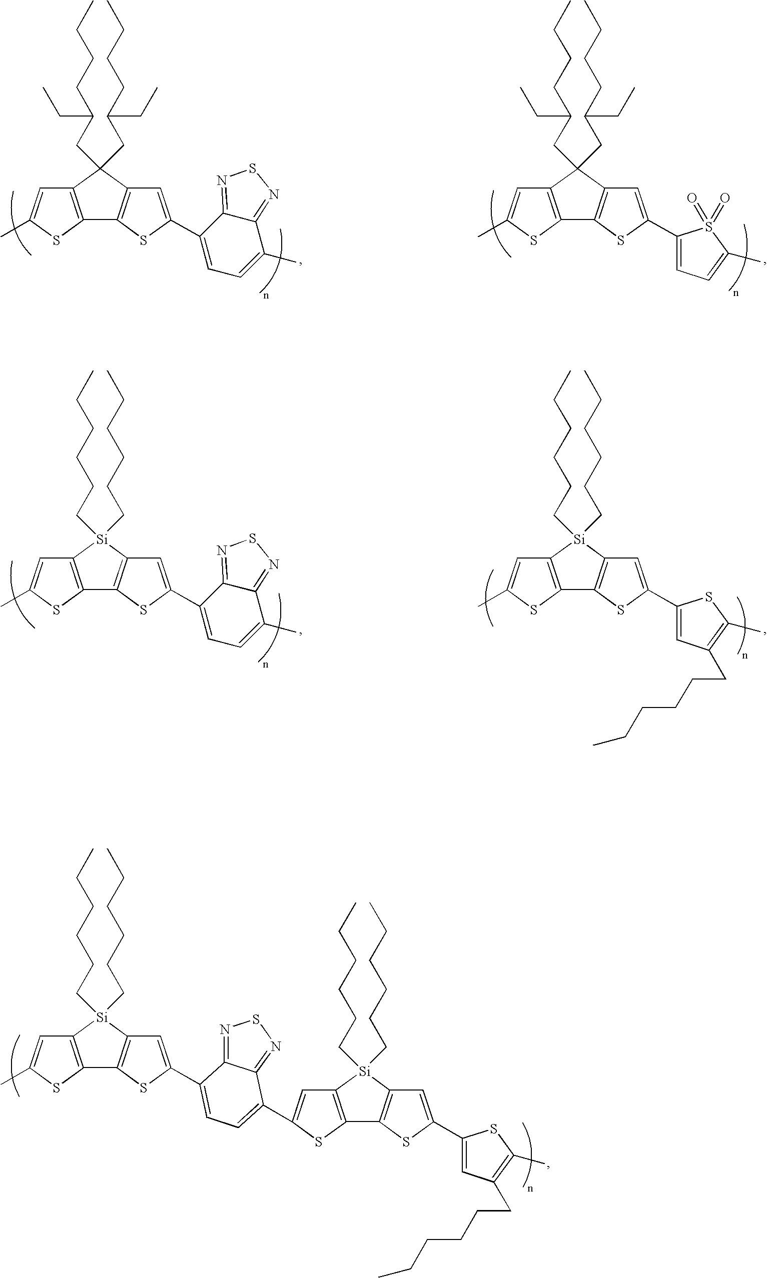 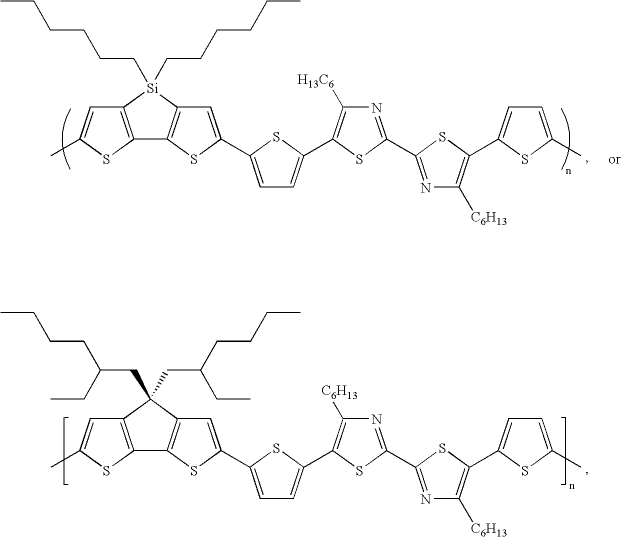
in which n can be an integer greater than 1.

The polymer can be either an electron donor material or an electron acceptor material.

The photovoltaic cell can be a tandem photovoltaic cell.

The photoactive material can include an electron acceptor material. In some embodiments, the electron acceptor material can be a fullerene (e.g., C61-phenyl-butyric acid methyl ester, PCBM).

The polymer and the electron acceptor material each can have a LUMO energy level. The LUMO energy level of the polymer can be at least about 0.2 eV (e.g., at least about 0.3 eV) less negative than the LUMO energy level of the electron acceptor material.

The photovoltaic cell can be disposed on a surface of a window blind between first and second window panes. In some embodiments, the window blind is foldable or rollable.

Embodiments can provide one or more of the following advantages.

In some embodiments, using a polymer containing a cyclopentadithiophene moiety, a silacyclopentadithiophene moiety, a cyclopentadithiazole moiety, a thiazolothiazole moiety, or a thiazole moiety can be advantageous because these moieties can contribute to a shift in the maximum absorption wavelength toward the red or near IR region of the electromagnetic spectrum. When such a polymer is incorporated into a photovoltaic cell, the current and efficiency of the cell can increase.

In some embodiments, substituted fullerenes or polymers containing substituted monomer repeat units (e.g., substituted with long-chain alkoxy groups such as oligomeric ethylene oxides or fluorinated alkoxy groups) can have improved solubility in organic solvents and can form an photoactive layer with improved morphology.

In some embodiments, a polymer described above can absorb light at a relatively long wavelength and have improved solubility in organic solvents. In some embodiments, such a polymer can be used to prepare an electron donor material with improved semiconductive properties.

In some embodiments, a photovoltaic cell containing a polymer described above can have a band gap that is relatively ideal for its intended purposes.

In some embodiments, a photovoltaic cell having high cell voltage can be created, whereby the HOMO level of the polymer is at least about 0.2 electron volts more negative relative to the LUMO or conduction band of an electron acceptor material.

In some embodiments, a photovoltaic cell containing a polymer described above can have relatively fast and efficient transfer of an electron to an electron acceptor material, whereby the LUMO of the donor is at least about 0.2 electron volt (e.g., at least about 0.3 electron volt) less negative than the conduction band of the electron acceptor material.

In some embodiments, a photovoltaic cell containing a polymer described above can have relatively fast charge separation, whereby the charge mobility of the positive charge, or hole, is relatively high and falls within the range of 10⁻⁴ to 10⁻¹ cm²/Vs.

In some embodiments, a polymer described above is soluble in an organic solvent and/or film forming.

In some embodiments, a polymer described above is optically non-scattering.

Other features and advantages of the invention will be apparent from the description, drawings, and claims.

### DESCRIPTION OF DRAWINGS

FIG. 1A is a front view of a window having a plurality of photovoltaic modules placed between two window panes.

FIG. 1B is a side view of a window have three window panes and a plurality of photovoltaic module placed between two of the three window panes.

FIG. 2 is a side view of a window having a foldable photovoltaic module placed between two window panes.

FIG. 3 is a side view of a window having a rollable photovoltaic module placed between two window panes.

FIG. 4 is a cross-sectional view of an embodiment of a photovoltaic cell.

FIG. 5 is a schematic of a system containing one electrode between two photoactive layers.

Like reference symbols in the various drawings indicate like elements.

### DETAILED DESCRIPTION

This invention generally relates to windows with photovoltaic cells (e.g., photovoltaic cells placed between two window panes).

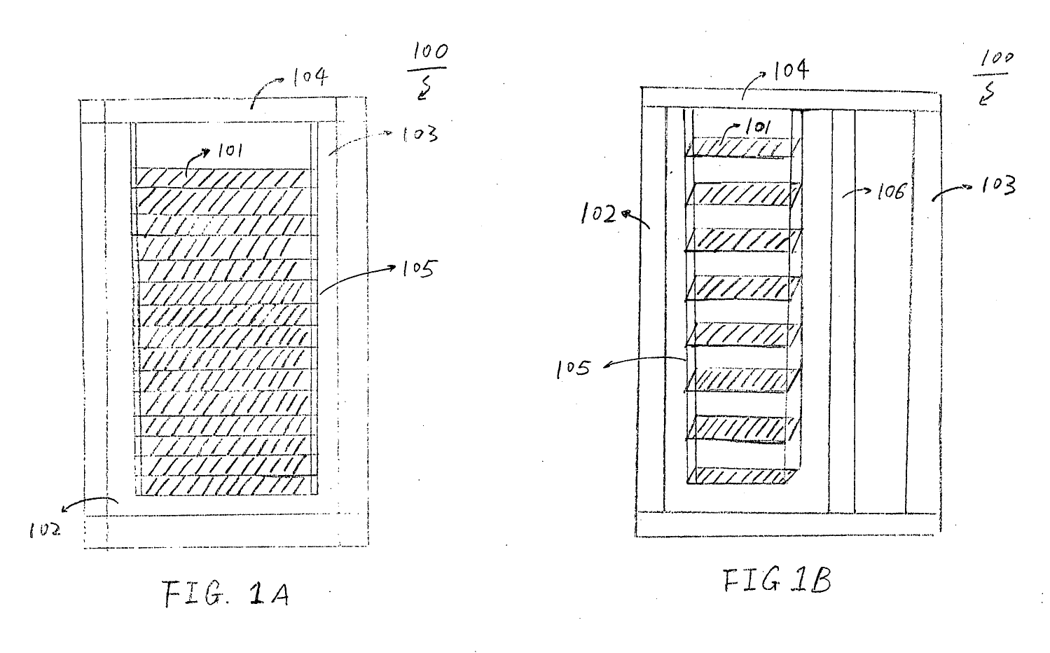

FIG. 1A illustrates a window 100 having a plurality of photovoltaic modules 101 placed between two window panes, i.e., front pane 102 and rear pane 103. Photovoltaic modules 101 include a plurality of photovoltaic cells and is in an extended configuration, which allows maximum light energy to be absorbed by the photovoltaic cells. The photovoltaic modules can absorb both outdoor light (e.g. sunlight) and indoor light.

FIG. 1B illustrates a window 100 having three window panes (i.e., front pane 102, rear pane 103, and middle pane 106) and a plurality of photovoltaic modules 101. Each photovoltaic module 101 includes a plurality of photovoltaic cells and is secured between front pane 102 and middle pane 106. Referring to FIG. 1B, photovoltaic modules 101 are shown in a non-extended configuration to allow light to enter a dwelling through window 100. Photovoltaic modules 101 can also be in a fully extended configuration (e.g., such as that shown in FIG. 1A) to capture the light passing through one of the window panes and convert absorbed light into electrical energy.

Photovoltaic modules 100 can be in any suitable shapes or patterns, such as dots, stripes, squares, circles, semi-circles, rectangles, triangles, diamonds, ellipses, trapezoids, or irregular shapes.

Referring to FIGS. 1A and 1B, window 100 can optionally include a support beam 104 and support strings 105 that are attached to support bean 104. Support strings 105 are used to mechanically contracts or extends photovoltaic modules 101.

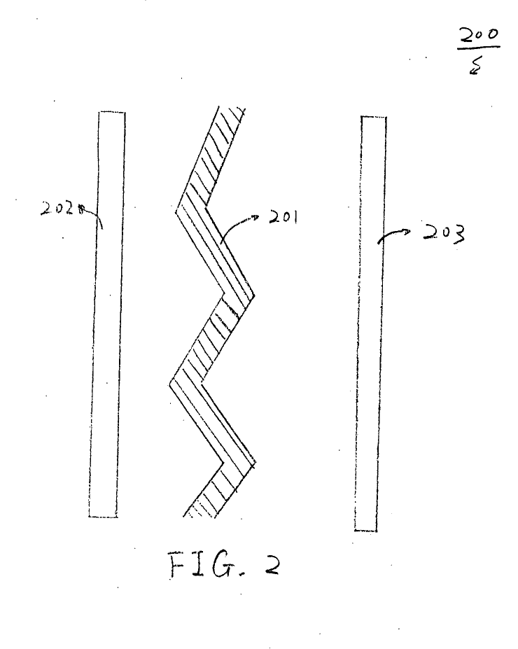

FIG. 2 illustrates a window 200 having a foldable photovoltaic module 201 placed between two window panes, i.e., front pane 202 and rear pane 203. Photovoltaic module 201 can be contracted to allow light to enter a dwelling through window 200. Photovoltaic module 201 can also be extended to capture light passing through one of the window panes and convert the absorbed light into electrical energy. In some embodiments, photovoltaic module 201 can be disposed on a foldable window blind between front pane 202 and rear pane 203.

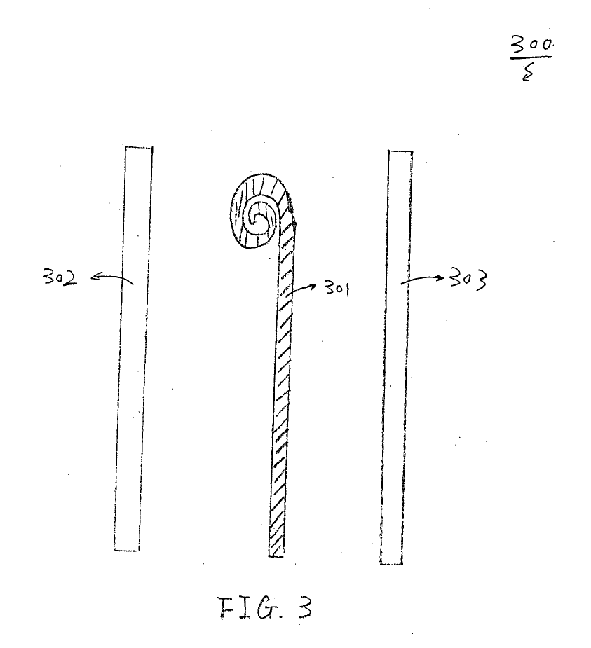

FIG. 3 illustrates a window 300 having a rollable photovoltaic module 301 placed between two window panes, i.e., front pane 302 and rear pane 303. Photovoltaic module 301 can be rolled up to allow light to enter a dwelling through window 300. Photovoltaic module 301 can also be extended to capture light passing through one of the window panes and convert the absorbed light into electrical energy. In some embodiments, photovoltaic module 301 can be disposed on a rollable window blind between front pane 302 and rear pane 303.

The photovoltaic modules described above also be placed on a window blind near the interior or exterior of an existing window. This approach circumvents the complete replacement of traditional windows and therefore is a less expensive option.

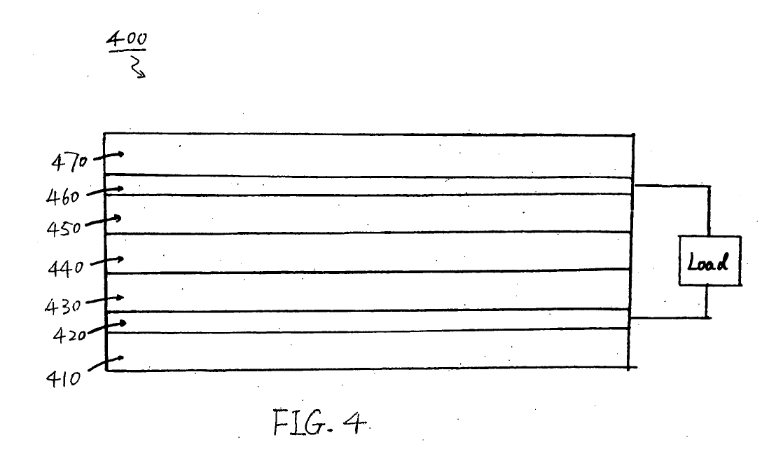

FIG. 4 shows a cross-sectional view of a photovoltaic cell 400 that includes a substrate 410, a cathode 420, a hole carrier layer 430, an active layer 440 (containing an electron acceptor material and an electron donor material), a hole blocking layer 450, an anode 460, and a substrate 470.

In general, during use, light impinges on the surface of substrate 410, and passes through substrate 410, cathode 420, and hole carrier layer 430. The light then interacts with active layer 440, causing electrons to be transferred from the electron donor material (e.g., a polymer described above) to the electron acceptor material (e.g., PCBM). The electron acceptor material then transmits the electrons through hole blocking layer 450 to anode 460, and the electron donor material transfers holes through hole carrier layer 430 to cathode 420. Anode 460 and cathode 420 are in electrical connection via an external load so that electrons pass from anode 460, through the load, and to cathode 420.

Electron acceptor materials of active layer 440 can include fullerenes. In some embodiments, active layer 440 can include one or more unsubstituted fullerenes and/or one or more substituted fullerenes. Examples of unsubstituted fullerenes include C_{60, C}₇₀, C₇₆, C₇₈, C₈₂, C₈₄, and C₉₂. Examples of substituted fullerenes include PCBM or fullerenes substituted with C₁-C₂₀ alkoxy optionally further substituted with C₁-C₂₀ alkoxy or halo (e.g., (OCH₂CH₂)₂OCH₃ or OCH₂CF₂OCF₂CF₂OCF₃). Without wishing to be bound by theory, it is believed that fullerenes substituted with long-chain alkoxy groups (e.g., oligomeric ethylene oxides) or fluorinated alkoxy groups have improved solubility in organic solvents and can form an photoactive layer with improved morphology.

In some embodiments, the electron acceptor materials can include polymers (e.g., homopolymers or copolymers). A polymers mentioned herein include at least two identical or different monomer repeat units (e.g., at least 5 monomer repeat units, at least 10 monomer repeat units, at least 50 monomer repeat units, at least 100 monomer repeat units, or at least 500 monomer repeat units). A copolymer mentioned herein refers to a polymer that includes at least two co-monomers of differing structures. In some embodiments, the polymers used as an electron acceptor material can include one or more monomer repeat units listed in Tables 1 and 2 below. Specifically, Table 1 lists examples of electron donating monomer repeat units that can serve as a conjugative link. Table 2 lists examples of electron withdrawing monomer repeat units. Note that depending on the substituents, monomer repeat units listed in Table 1 can be electron withdrawing and monomer repeat units listed in Table 2 can also be electron donating. Preferably, the polymers used as an electron acceptor material include a high molar percentage (e.g., at least about 50%, at least about 60%, at least about 70%, at least about 80%, at least about 90%) of an electron withdrawing monomer repeat unit.

Electron donor materials of active layer 440 can include polymers (e.g., homopolymers or copolymers). In some embodiments, the polymers used as an electron donor material can include one or more monomer repeat units listed in Tables 1 and 2. Preferably, the polymers used as an electron donor material include a high molar percentage (e.g., at least about 50%, at least about 60%, at least about 70%, at least about 80%, at least about 90%) of an electron donating monomer repeat unit. In some embodiments, the polymers include a monomer repeat unit containing C₁-C₂₀ alkoxy on a ring, which is optionally further substituted with C₁-C₂₀ alkoxy or halo (e.g., (OCH₂CH₂)₂OCH₃ or OCH₂CF₂OCF₂CF₂OCF₃). Without wishing to be bound by theory, it is believed that polymers containing monomer repeat units substituted with long-chain alkoxy groups (e.g., oligomeric ethylene oxides) or fluorinated alkoxy groups have improved solubility in organic solvents and can form an photoactive layer with improved morphology.

TABLE 1

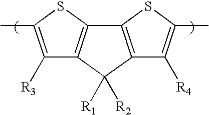

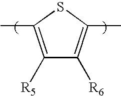

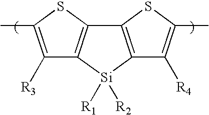

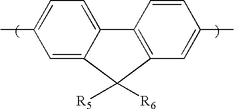

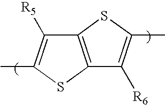

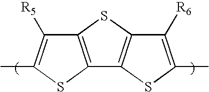

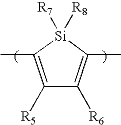

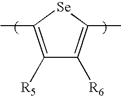

TABLE 2

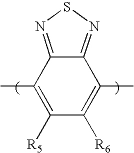

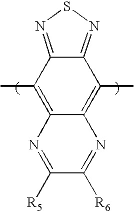

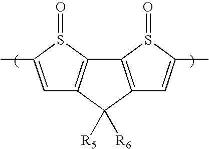

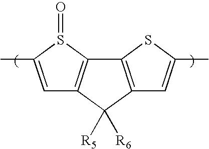

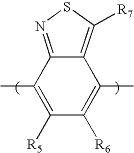

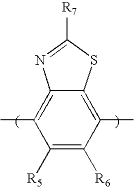

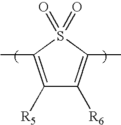

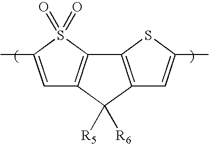

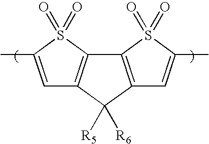

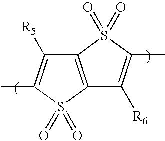

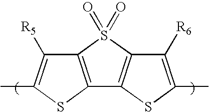

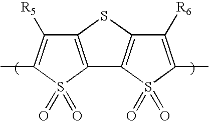

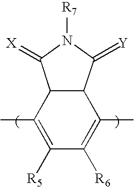

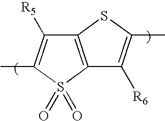

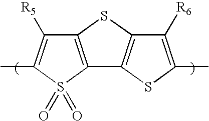

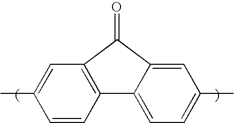

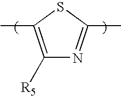

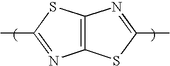

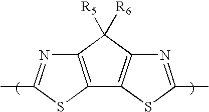

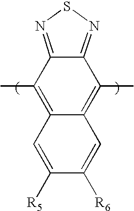

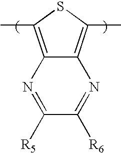

Referring to formulas listed in Tables 1 and 2 above, each of X and Y, independently, can be CH₂, O, or S; each of R₁, R₂, R₃, R₄, R₅, and R6, independently, can be H, C₁-C₂₀ alkyl (e.g., branched alkyl or perflorinated alkyl), C₁-C₂₀ alkoxy, C₃-C₂₀ cycloalkyl, C₁-C₂₀ heterocycloalkyl, aryl (e.g., phenyl or substituted phenyl), heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl; and each of R₇ and R₈, independently, is H, C₁-C₂₀ alkyl, C₁-C₂₀ alkoxy, aryl, heteroaryl, C₃-C₂₀ cycloalkyl, or C₃-C₂₀ heterocycloalkyl.

An alkyl can be saturated or unsaturated and branch or straight chained. A C₁-C₂₀ alkyl contains 1 to 20 carbon atoms (e.g., one, two , three, four, five, six, seven, eight, nine, 10, 11, 12, 13, 14, 15, 16, 17, 18, 19, and 20 carbon atoms). Examples of alkyl moieties include —CH₃, —CH₂—, —CH₂═CH₂—, —CH₂—CH═CH₂, and branched —C₃H₇. An alkoxy can be branch or straight chained and saturated or unsaturated. An C₁-C₂₀ alkoxy contains an oxygen radical and 1 to 20 carbon atoms (e.g., one, two , three, four, five, six, seven, eight, nine, 10, 11, 12, 13, 14, 15, 16, 17, 18, 19, and 20 carbon atoms). Examples of alkoxy moieties include —OCH₃ and —OCH═CH—CH₃. A cycloalkyl can be either saturated or unsaturated. A C₃-C₂₀ cycloalkyl contains 3 to 20 carbon atoms (e.g., three, four, five, six, seven, eight, nine, 10, 11, 12, 13, 14, 15, 16, 17, 18, 19, and 20 carbon atoms). Examples of cycloalkyl moieities include cyclohexyl and cyclohexen-3-yl. A heterocycloalkyl can also be either saturated or unsaturated. A C₃-C₂₀ heterocycloalkyl contains at least one ring heteroatom (e.g., O, N, and S) and 3 to 20 carbon atoms (e.g., three, four, five, six, seven, eight, nine, 10, 11, 12, 13, 14, 15, 16, 17, 18, 19, and 20 carbon atoms). Examples of heterocycloalkyl moieties include 4-tetrahydropyranyl and 4-pyranyl. An aryl can contain one or more aromatic rings. Examples of aryl moieties include phenyl, phenylene, naphthyl, naphthylene, pyrenyl, anthryl, and phenanthryl. A heteroaryl can contain one or more aromatic rings, at least one of which contains at least one ring heteroatom (e.g., O, N, and S). Examples of heteroaryl moieties include furyl, furylene, fluorenyl, pyrrolyl, thienyl, oxazolyl, imidazolyl, thiazolyl, pyridyl, pyrimidinyl, quinazolinyl, quinolyl, isoquinolyl, and indolyl.

Alkyl, alkoxy, cycloalkyl, heterocycloalkyl, aryl, and heteroaryl mentioned herein include both substituted and unsubstituted moieties, unless specified otherwise. Examples of substituents on cycloalkyl, heterocycloalkyl, aryl, and heteroaryl include C₁-C₂₀ alkyl, C₃-C₂₀ cycloalkyl, C₁-C₂₀ alkoxy, aryl, aryloxy, heteroaryl, heteroaryloxy, amino, C₁-C₁₀ alkylamino, C₁-C₂₀ dialkylamino, arylamino, diarylamino, hydroxyl, halogen, thio, C₁-C₁₀ alkylthio, arylthio, C₁-C₁₀ alkylsulfonyl, arylsulfonyl, cyano, nitro, acyl, acyloxy, carboxyl, and carboxylic ester. Examples of substituents on alkyl include all of the above-recited substituents except C₁-C₂₀ alkyl. Cycloalkyl, heterocycloalkyl, aryl, and heteroaryl also include fused groups.

The monomers for preparing the polymers mentioned herein may contain a non-aromatic double bond and one or more asymmetric centers. Thus, they can occur as racemates and racemic mixtures, single enantiomers, individual diastereomers, diastereomeric mixtures, and cis- or trans- isomeric forms. All such isomeric forms are contemplated.

The copolymers described above can be prepared by methods known in the art. For example, a copolymer can be prepared by a cross-coupling reaction between one or more comonomers containing two alkylstannyl groups and one or more comonomers containing two halo groups in the presence of a transition metal catalyst. As another example, a copolymer can be prepared by a cross-coupling reaction between one or more comonomers containing two borate groups and one or more comonomers containing two halo groups in the presence of a transition metal catalyst. The comonomers can be prepared by the methods described herein or by the methods know in the art, such as those described in U.S. patent application Ser. No. 11/486,536, Coppo et al., Macromolecules 2003, 36, 2705-2711 and Kurt et al., J. Heterocycl. Chem. 1970, 6, 629, the contents of which are hereby incorporated by reference.

Table 3 below lists seven exemplary polymers (i.e., polymers 1-7) described in the Summary section above. These polymers can have unique properties, which make them particularly suitable as charge carriers in the active layer of a photovoltaic cell. Polymers 1 and 3-7 can be obtained by the methods described in Examples 1 -10 below.

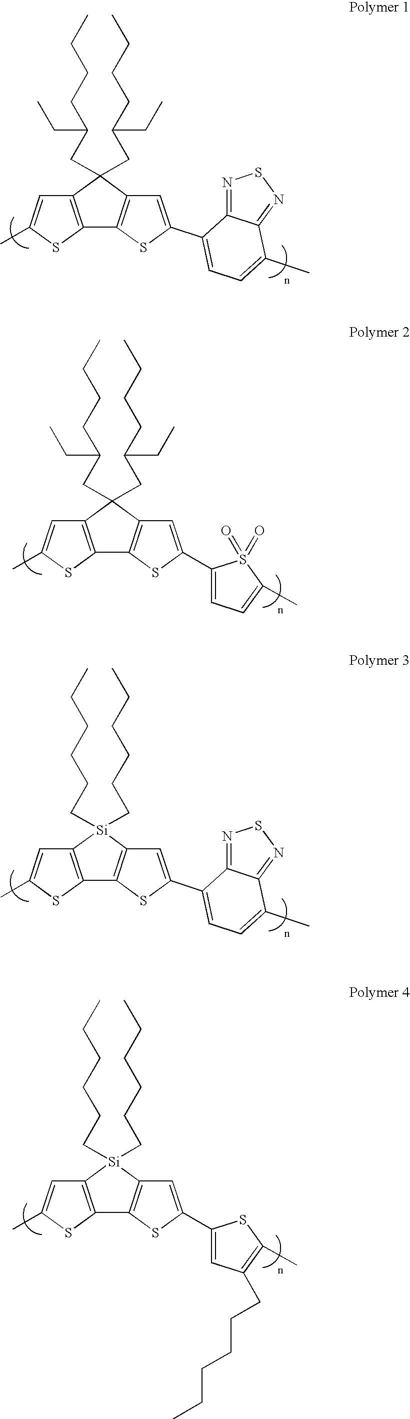

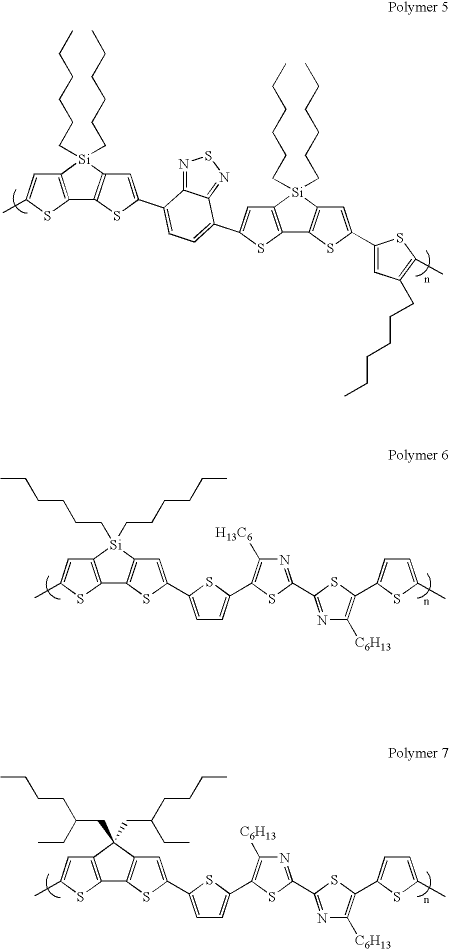

Generally, one co-monomer in the polymers described in the Summary section above is a silacyclopentadithiophene. An advantage of a co-polymer containing a silacyclopentadithiophene moiety is that its absorption wavelength can shift toward the red and near IR portion (e.g., 650-800 nm) of the electromagnetic spectrum, which is not accessible by most other polymers. When such a co-polymer is incorporated into a photovoltaic cell, it enables the cell to absorb the light in this region of the spectrum, thereby increasing the current and efficiency of the cell.

The polymers described above can be useful in solar power technology because the band gap is close to ideal for a photovoltaic cell (e.g., a polymer-fullerene cell). The HOMO level of the polymers can be positioned correctly relative to the LUMO of an electron acceptor (e.g., PCBM) in a photovoltaic cell (e.g., a polymer-fullerene cell), allowing for high cell voltage. The LUMO of the polymers can be positioned correctly relative to the conduction band of the electron acceptor in a photovoltaic cell, thereby creating efficient transfer of an electron to the electron acceptor. For example, using a polymer having a band gap of about 1.4-1.6 eV can significantly enhance cell voltage. Cell performance, specifically efficiency, cam benefit from both an increase in photocurrent and an increase in cell voltage, and can approach and even exceed 15% efficiency. The positive charge mobility of the polymers can be relatively high and approximately in the range of 10⁻⁴ to 10⁻¹ cm²/Vs. In general, the relatively high positive charge mobility allows for relatively fast charge separation. The polymers can also be soluble in an organic solvent and/or film forming. Further, the polymers can be optically non-scattering.

Components in photovoltaic cell other than the electron acceptor materials and the electron donor materials are known in the art, such as those described in U.S. patent application Ser. No. 10/723,554, the contents of which are incorporated herein by references.

In some embodiments, the polymer described above can be used as an electron donor material or an electro acceptor material in a system in which two photovoltaic cells share a common electrode. Such a system is also known as tandem photovoltaic cell. Examples of tandem photovoltaic cells are discussed in U.S. patent application Ser. No. 10/558,878, filed Nov. 29, 2005, the contents of which are hereby incorporated by reference.

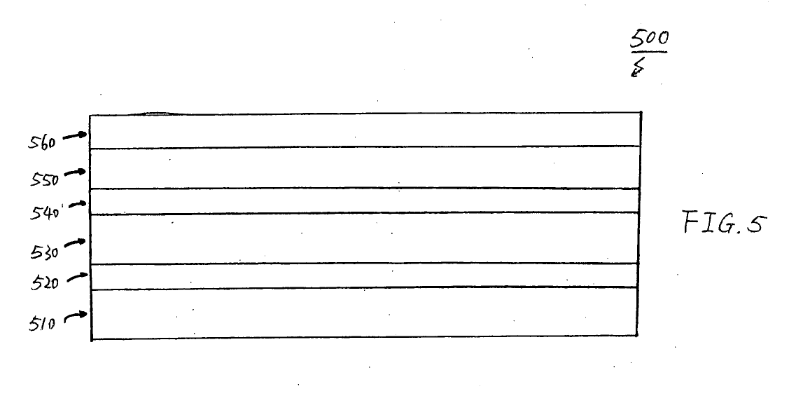

As an example, FIG. 5 is a schematic of a tandem photovoltaic cell 500 having a substrate 510, three electrodes 520, 540, and 560, and two photoactive layers 530 and 550. Electrode 540 is shared between photoactive layers 530 and 550, and is electrically connected with electrodes 520 and 560. In general, electrodes 520, 540, and 560 can be formed of an electrically conductive material, such as those described in U.S. patent application Ser. No. 10/723,554. In some embodiments, one or more (i.e., one, two, or three) electrodes 520, 540, and 560 is a mesh electrode. In some embodiments, one or more electrodes 520, 540, and 560 is formed of a semiconductive material. Examples of semiconductive materials include titanium oxides, indium tin oxides, fluorinated tin oxides, tin oxides, and zinc oxides. In certain embodiments, one or more (i.e., one, two, or three) electrodes 520, 540, and 560 are formed of titanium dioxide. Titanium dioxide used to prepare an electrode can be in any suitable forms. For example, titanium dioxide can be in the form of interconnected nanoparticles. Examples of interconnected titanium dioxide nanoparticles are described, for example, in U.S. Pat. No. 7,022,910, the contents of which are incorporated herein by reference. In some embodiments, at least one (e.g., one, two, or three) of electrodes 520, 540, and 560 is a transparent electrode. As referred to herein, a transparent electrode is formed of a material which, at the thickness used in a photovoltaic cell, transmits at least about 60% (e.g., at least about 70%, at least about 75%, at least about 80%, at least about 85%, at least about 90%, at least about 95%) of incident light at a wavelength or a range of wavelengths used during operation of the photovoltaic cell. In certain embodiments, both electrodes 520 and 560 are transparent electrodes.

Each of photoactive layers 530 and 550 can contain at least one semiconductive material. In some embodiments, the semiconductive material in photoactive layer 530 has the same band gap as the semiconductive material in photoactive layer 550. In certain embodiments, the semiconductive material in photoactive layer 530 has a band gap different from that of the semiconductive material in photoactive layer 550. Without wishing to be bound by theory, it is believed that incident light not absorbed by one photoactive layer can be absorbed by the other photoactive layer, thereby maximizing the absorption of the incident light.

In some embodiments, at least one of photoactive layers 530 and 550 can contain an electron acceptor material (e.g., PCBM or a polymer described above) and an electron donor material (e.g., a polymer described above). In general, suitable electron acceptor materials and electron donor materials can be those described above. In certain embodiments, each of photoactive layers 530 and 550 contains an electron acceptor material and an electron donor material.

Substrate 510 can be formed of one or more suitable polymers, such as those described in U.S. patent application Ser. No. 10/723,554. In some embodiments, an additional substrate (not shown in FIG. 5) can be disposed on electrode 560.

Photovoltaic cell 500 can further contain a hole carrier layer (not shown in FIG. 5) and a hole blocking layer (not shown in FIG. 5), such as those described in U.S. patent application Ser. No. 10/723,554.

While photovoltaic cells have been described above, in some embodiments, the polymers described herein can be used in other devices and systems. For example, the polymers can be used in suitable organic semiconductive devices, such as field effect transistors, photodetectors (e.g., IR detectors), photovoltaic detectors, imaging devices (e.g., RGB imaging devices for cameras or medical imaging systems), light emitting diodes (LEDs) (e.g., organic LEDs or IR or near IR LEDs), lasing devices, conversion layers (e.g., layers that convert visible emission into IR emission), amplifiers and emitters for telecommunication (e.g., dopants for fibers), storage elements (e.g., holographic storage elements), and electrochromic devices (e.g., electrochromic displays).

The following examples are illustrative and not intended to be limiting.

### EXAMPLE 1

### Synthesis of 4,4-Bis-(2-ethyl-hexyl)-4H-cyclopenta[2,1-b;3,4-b′]dithiophene

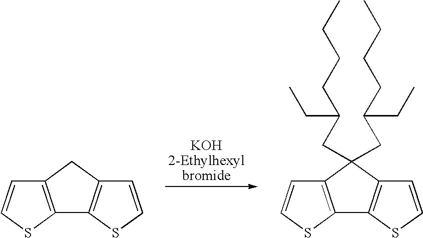

4H-Cyclopenta[2,1-b;3,4-b′]dithiophene (1.5 g, 0.00843 mol) was dissolved in DMSO (50 mL). After the solution was purged with nitrogen, and grounded KOH (1.89 g, 0.0337 mol), sodium iodide (50 mg), and 2-ethylhexyl bromide (3.25 g, 0.0169 mol) were sequentially added. The reaction mixture was stirred overnight under nitrogen (c.a. 16 hours). Water was added and the reaction was extracted with t-butylmethyl ether. The organic layer was collected, dried over magnesium sulfate, and concentrated. The residue was purified by chromatography using hexanes as eluent. Fractions containing pure 4,4-Bis-(2-ethyl-hexyl)-4H-cyclopenta[2,1-b;3,4-b′]dithiophene product were combined and concentrated. The product was obtained as a colorless oil after drying under vacuum. Yield: 2.68 g (79%). ¹H NMR (CDCl₃, 250 MHz): 7.13 (m, 2H), 6.94 (m, 2H), 1.88 (m, 4H), 0.94 (m, 16H), 0.78 (t, 6.4 Hz, 6H), 0.61 (t, 7.3 Hz, 6H).

### EXAMPLE 2

### Synthesis of 4,4-Bis-(2-ethyl-hexyl)-2,6-bis-trimethylstannanyl-4H-cyclopenta[2,1-b;3,4-b′]dithiophene

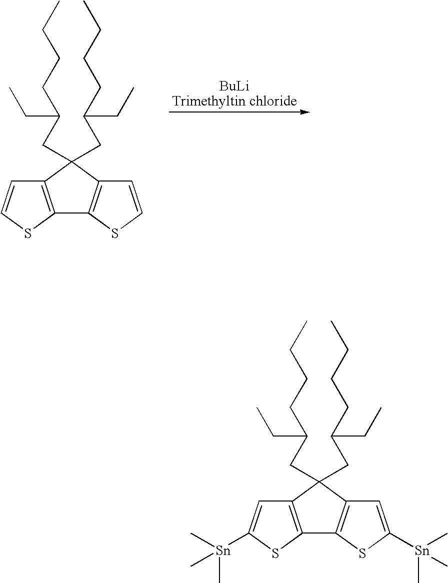

Starting material 4,4-Bis-(2-ethyl-hexyl)-4H-cyclopenta[2,1-b;3,4-b′]dithiophene (1.5 g, 0.00372 mol) was dissolved in dry THF (20 mL). After the solution was cooled to −78° C., butyl lithium (5.21 mL, 0.0130 mol) was added dropwise. The reaction mixture was stirred at this temperature for 1 hour. It was then warmed to room temperature and stirred for another 3 hours. The mixture was again cooled to −78° C. and trimethyltin chloride (1 M in hexane, 15.6 mL, 15.6 mmol) was added dropwise. The reaction mixture was allowed to warm to room temperature and stirred overnight (c.a. 16 hours).

Water was added and the reaction was extracted with toluene. The organic layer was washed with water, dried over sodium sulfate, and concentrated. The residue was dissolved in toluene, and quickly passed through a small plug of silica gel pretreated with triethylamine. The solvent was removed and the residue was dried under vacuum. 1.25 g of the product was obtained. ¹H NMR (CDCl₃, 250 MHz): 6.96 (m, 2H), 1.85 (m, 4H), 1.29 (m, 2H), 0.92 (m, 16H), 0.78 (t, 6.8 Hz, 6H), 0.61 (t, 7.3 Hz, 6H), 0.38 (m, 18H).

### EXAMPLE 3

### Polymerization of Bis-(trimethylstannyl)-4,4-Di(2-ethylhexyl)-cyclopenta[2,1-b:3,4-b′]dithiophen and 4,7-dibromo-2,1,3-benzothiadiazole

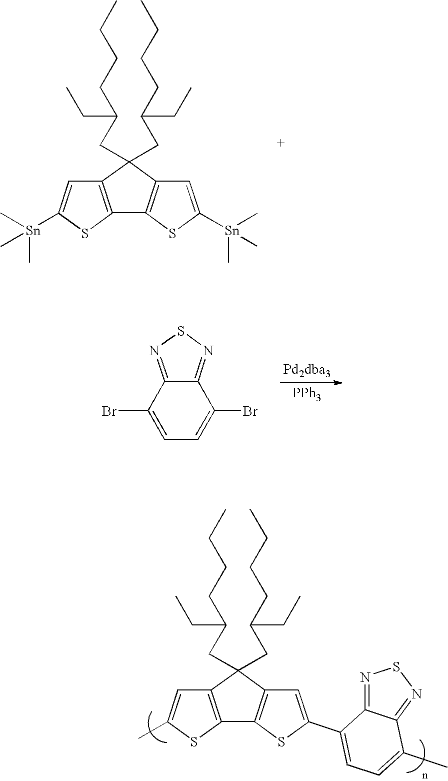

Bis-(trimethylstannyl)-4,4-di(2-ethylhexyl)-cyclopenta[2,1-b:3,4-b′]dithiophene (0.686 g, 0.000943 mol) and 4,7-dibromo-2,1,3-benzothiadiazole (0.269 g, 0.000915 mol) were dissolved in toluene (20 mL). After the reaction was purged with nitrogen, tris(dibenzylideneacetone)dipalladium(0) (25.1 mg, 0.0275 mmol) and triphenylphosphine (57.6 mg, 0.220 mmol) were added. The reaction was further purged with nitrogen for 10 minutes and heated to 120° C. under nitrogen for 24 hours. The solvent was removed under vacuum and the residue was dissolved in chloroform. After the mixture was poured into methanol (500 mL), the blue precipitate thus obtained was collected by filtration, washed with methanol, and dried. The precipitate was dissolved in chloroform (30 mL) under heating, and filtered through a 0.45 μm membrane. The solution was loaded on to recycling HPLC (2H+2.5H column on a Dychrome recycling HPLC, 5 cycles for each injection), in 3 mL portions for purification. Higher-molecular-weight fractions were combined to give 120 mg pure polymer (Mn=35 kDa).

### EXAMPLE 4

### Synthesis of bis-(5,5′-trimethylstannyl)-3,3′-di-n-hexyl-silylene-2,2′-dithiophene

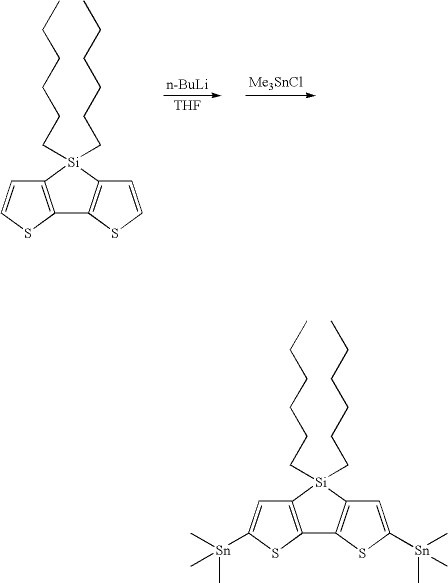

0.638 g (1.76 mmol) of 3,3′-di-n-hexylsilylene-2,2′-dithiophene (prepared according to the procedures described in Usta et al., J. Am. Chem. Soc., 2006; 128(28); 9034-9035, the contents of which are hereby incorporated by reference) was dissolved in 20 mL of freshly distilled dry THF. The solution was purged with nitrogen for 15 minutes and cooled to −78° C. 4.00 mL of n-butyl lithium in hexane (10 mmol) was added to this solution dropwise. The solution was allowed to react for two hours at this temperature. Te solution was then warmed to room temperature and allowed to react for additional two and half hours. After the solution was subsequently cooled down to −78° C., 12.00 ml (12.00 mmol) of trimethyltin chloride in hexane was added into the solution dropwise. The reaction solution was stirred at −78° C. for two more hours. The solution was then warmed to room temperature and allowed to react for 16 more hours. Upon the completion of reaction, 100 ml of distilled water was added and the solution was extracted using toluene (3×60 ml). The combined organic phase was washed with distilled water (3×150 ml) and dried over sodium sulfate. The organic solvent was removed via rotary evaporation under vacuum. The residue was dissolved in toluene and quickly passed through a silica-gel pad pretreated with triethyl amine. The organic solvent was removed under vacuum to give the title compound (1.048 g). The yield was about 86.50%. ¹H NMR in CDCl₃: 7.00 (m, 2H), 1.25-1.42 (m, 16H), 0.86-0.94 (m, 10H), and 0.38 (m, 18H).

### EXAMPLE 5

### Polymerization of bis-(5,5′-trimethylstannyl)-3,3′-di-n-hexyl-silylene-2,2′-dithiophene and 4,7-dibromo-2,13-benzothiadiazole

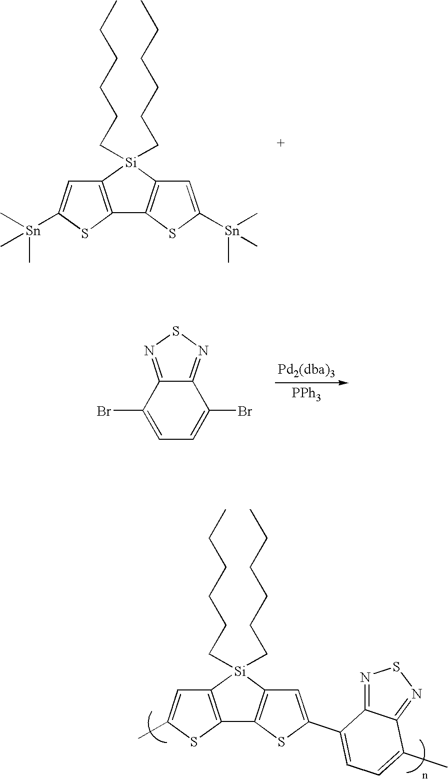

0.353 g (0.513 mmol) of bis-(5,5′-trimethylstannyl)-3,3′-di-n-hexyl-silylene-2,2′-dithiophene and 0.135 g (0.500 mmol) (monomer ratio=1.025) of 4,7-dibromo-2,1,3-benzothiadiazole were dissolved in 12 mL of anhydrous toluene. After the solution was purged with nitrogen, 12.55 mg (0.014 mmol) of tris(dibenzylideneacetone)dipalladium (0) and 28.80 mg (0.110 mmol) of triphenylphosphine were added. The solution was further purged with nitrogen for 15 minutes. The solution was then heated up to 110-120° C. and allowed to react for 40 hours. Upon the completion of the reaction, the solvent was removed via rotary evaporation. The resultant residue was dissolved in about 30 mL of chlorobenzene. After the chlorobenzene solution was poured into 600 mL of methanol, a deep blue precipitate thus obtained (the crude polymer product) was collected through filtration. The collected solid was redissolved in about 40 mL of chlorobenzene during heating. The chlorobenzene solution was filtered through a 0.45μ membrane, and poured into 600 mL of methanol. After the dark blue color polymer product thus obtained was collected through filtration, it was washed with methanol (3×100 ml) and dried under vacuum.

The dried polymer product was redissolved in 60 ml of hot chlorobenzene and poured into 60 mL of 7.5% sodium diethyldithiocarbamate trihydrate (DDC) aqueous solution. The solution was purged by nitrogen for 15 minutes. The mixed two phase solution thus obtained was heated at about 80° C. and stirred vigorously under nitrogen for 15 hours. After the organic phase was washed with hot distilled water (3×60 ml), it was slowly poured into 800 mL of methanol. The precipitate was collected through filtration. The collected polymer product was first extracted with acetone and methanol each for 12 hours through Soxhlet extraction apparatus. The polymer product was then collected and dried. The molecular weight distribution of the polymer product was analyzed using HPLC through a GPC column with polystyrene as a reference (HPLC Instrument: Agilent Technologies., Model No. 1090M. HPLC Column: PL Gel 10M Mixed B. Solvent used: Chlorobenzene). The measured molecular weight distributions are: Mₙ=4,000 and M_{w}=5,000. λₘₐₓ. (nm) (in chlorobenzene)=641 nm. λₘₐₓ. (nm) (thin film)=673 nm.

HOMO (eV)=−5.47 (from electrochemical measurement), LUMO (eV)=−3.69 (from electrochemical measurement), and 1.78 eV for the value of band gap (calculated from electrochemical measurement results).

### EXAMPLE 6

### Polymerization of bis-(5,5′-trimethylstannyl)-3,3′-di-n-hexyl-silylene-2,2′-dithiophene and 3-hexyl-2,5-dibromo-thiophene

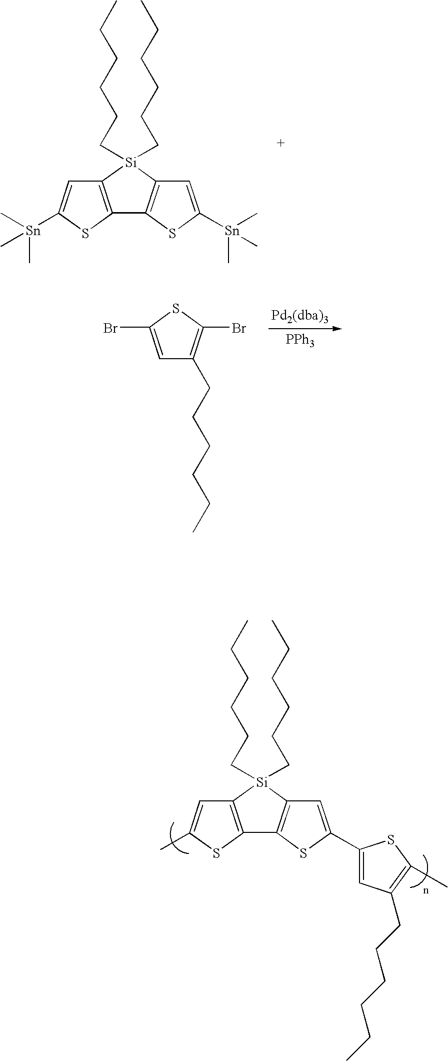

0.353 g (0.513 mmol) of bis-(5,5′-trimethylstannyl)-3,3′-di-n-hexyl-silylene-2,2′-dithiophene and 0.163 g (0.500 mmol) (monomer ratio=1.025) of 3-hexyl-2,5-dibromothiophene were dissolved in 12 mL of anhydrous toluene. After the solution was purged with nitrogen, 12.55 mg (0.014 mmol) of tris (dibenzylideneacetone) dipalladium (0) and 28.80 mg (0.110 mmol) of triphenylphosphine were added. The solution was further purged with nitrogen for 15 minutes. The solution was then heated up to 110-120° C. and allowed to react for 40 hours. Upon the completion of the reaction, the solvent was removed via rotary evaporation. The resultant residue was washed with methanol (50 mL×3), and then washed with of acetone (3×50 ml). The residue of the polymer product was collected as dark red-purple solid. The collected polymer product was redissolved in about 60 mL of chloroform under heating. After the chloroform solution was filtered through a 0.45μ membrane, the solvent was removed via rotary evaporation under vacuum. The polymer product was then dried under vacuum.

The dried polymer product was redissolved in 60 ml of hot toluene. The solution was poured into 60 mL of 7.5% DDC aqueous solution. The solution was purged by nitrogen for 15 minutes. The mixed two phase solution thus obtained was heated at about 80° C. and stirred vigorously under nitrogen protection for 12 hours. After the organic phase was then washed with hot distilled water (3×60 ml), the organic phase was collected and dried over anhydrous magnesium sulfate. The solvent was removed to give a solid polymer product. The solid polymer product was sequentially extracted with methanol and acetone for 12 hours each through Soxhlet extraction apparatus. Finally, the polymer product was collected and dried. The molecular weight distribution of the polymer was analyzed using HPLC through a GPC column with polystyrene as a reference (HPLC Instrument: Agilent Technologies, Model No. 1090M. HPLC Column: PL Gel 10M Mixed B. Solvent used: Chlorobenzene). The measured molecular weight distributions are: Mₙ=10,000 and M_{w}=13,500. λₘₐₓ. (nm) (in chlorobenzene)=501 nm. λₘₐₓ. (nm) (thin film)=503 nm.

### EXAMPLE 7

### Polymerization of bis-(5,5′-trimethylstannyl)-3,3′-di-n-hexyl-silylene-2,2′-dithiophene, 4,7-dibromo-2,13-benzothiadiazole, and 3-hexyl-2,5-dibromo-thiophene

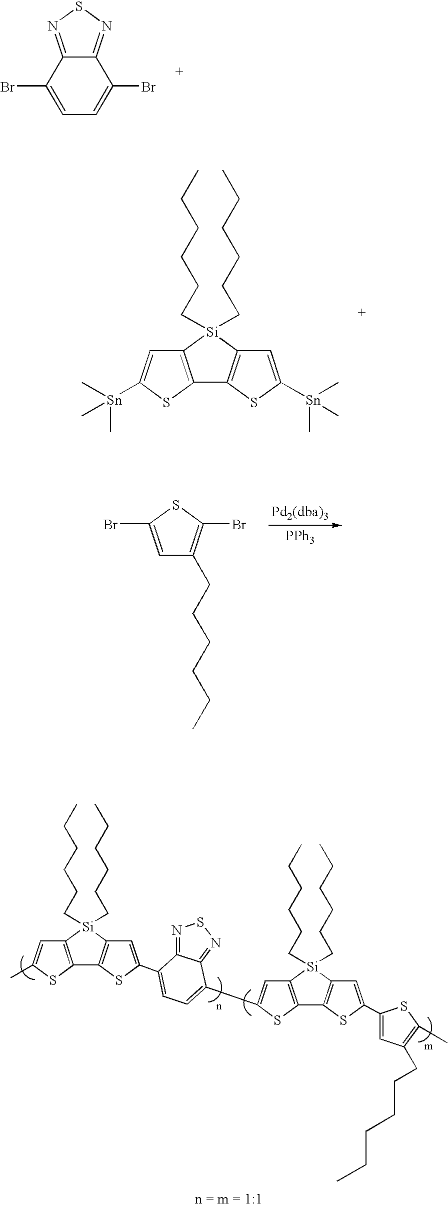

0.310 g (0.450 mmol) of bis-(5,5′-trimethylstannyl)-3,3′-di-n-hexyl-silylene-2,2′-dithiophene, 0.068 g (0.225 mmol) (monomer ratio=1.025) of 4,7-dibromo-2,1,3-benzothiadiazole, and 0.073 g (0.225 mmol) of 3-hexyl-2,5-dibromothiophene (monomer ratio=2:1:1) were dissolved in 12 mL of anhydrous toluene. After the solution was purged with nitrogen, 12.55 mg (0.014 mmol) of tris(dibenzylideneacetone)dipalladium(0) and 28.80 mg (0.110 mmol) of triphenylphosphine were added. The solution was further purged with nitrogen for 15 minutes. The solution was then heated up to 110-120° C. and allowed to react for 40 hours. Upon the completion of the reaction, the solvent was removed via rotary evaporation. The resultant residue was dissolved in about 30 mL of chlorobenzene. After the solution was poured into 600 mL of methanol, deep blue-black precipitate was collected through filtration. The collected solid polymer product was then redissolved in about 40 mL of chlorobenzene under heating. After the chlorobenzene solution was filtered through a 0.45μ membrane, it was poured into 600 mL of methanol. The dark blue-black color polymer product was collected again through filtration. The solid polymer product was washed with methanol (3×100 ml) and dried under vacuum.

The dried polymer product was redissolved in 60 ml of hot chlorobenzene and poured into 60 mL of 7.5% DDC aqueous solution. The solution was purged by nitrogen for 15 minutes. The mixed two phase solution thus obtained was heated at about 80° C. and stirred vigorously under nitrogen protection for 15 hours. The organic phase was then washed by hot distilled water (3×60 ml). After the chlorobenzene solution was slowly poured into 800 ml of methanol, the precipitate thus obtained was collected through filtration. The collected solid polymer product was sequentially extracted with acetone and methanol for 12 hours each through Soxhlet extraction apparatus. The polymer product was then collected and dried. The molecular weight distribution of the polymer was analyzed using HPLC through a GPC column with polystyrene as a reference (HPLC Instrument: Agilent Technologies, Model No. 1090M. HPLC Column: PL Gel 10M Mixed B. Solvent used: Chlorobenzene). The measured molecular weight distributions are: Mₙ=7,500 and M_{w}=10,400. λₘₐₓ. (nm) (in chlorobenzene)=595 nm. λₘₐₓ. (nm) (thin film)=649 nm.

### EXAMPLE 8

### Polymerization of bis-(5,5′-trimethylstannyl)-3,3′-di-n-hexyl-silylene-2,2′-dithiophene and 5,5′-bis(5-bromo-2-thienyl)-4,4′-dihexyl-2,2′-bithiazole

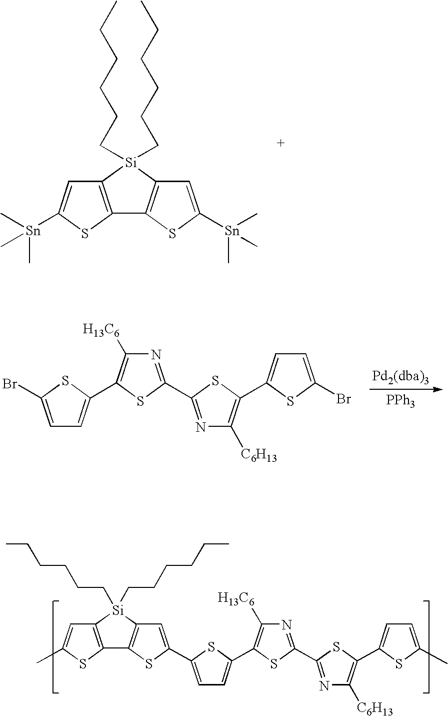

A 100 mL Schlenk flask was charged with 0.045 g (0.0654 mmol) of bis-(5,5′-trimethylstannyl)-3,3′-di-n-hexyl-silylene-2,2′-dithiophene, 0.043 g (0.0654 mmol) of 5,5′-bis(5-bromo-2-thienyl)-4,4′-dihexyl-2,2′-bithiazole, 1.0 mg (0.00109 mmol) of Pd₂dba₃, and 2.0 mg (0.0076 mmol) of PPh₃. The flask was evacuated and refilled with argon three times. The solids were dissolved in 3 mL of o-xylene and the solution was heated to 95° C. for 24 hours. The solution was then cooled, poured into 500 mL of stirring MeOH, and filtered. The dark precipitate thus obtained was washed with MeOH, dried under vacuum to give a brown solid (0.069 g). Mn=3.7 kDa. Mw=4.6 kDa.

### EXAMPLE 9

### Preparation of 2,6-bis(4,4,5,5-tetramethyl-1,3,2-dioxaborolan-2-yl)-4H-4,4-bis(2 ′-ethylhexyl)cyclopenta[2,1-b:3,4-b′]thiophene

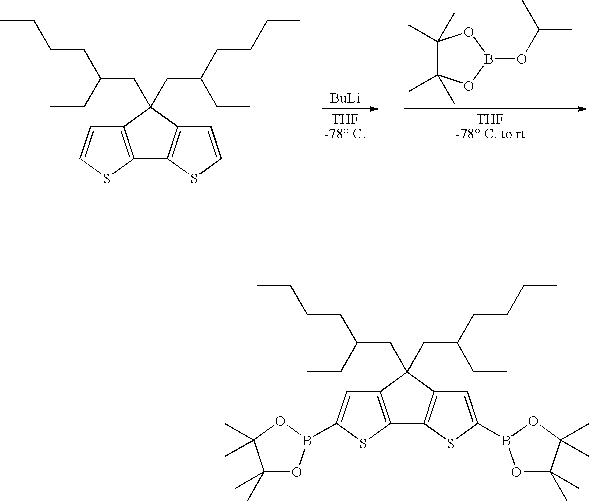

100 mL oven dried Schlenk flask was charged with 1.097 g (2.72 mmol) of 4H-4,4-bis(2′-ethylhexyl)cyclopenta[2,1-b:3,4-b′]dithiophene. The flask was evacuated and purged with argon three times. To this flask was then added 20 mL of dry, distilled THF. The resulting solution was cooled to −78° C. and 4.35 mL (10.88 mmol, 4 equv.) of 2.5M BuLi was added dropwise. The reaction was stirred for 1 hout at −78° C. and then warmed to room temperature and stirred for an additional 3 hours. The solution was cooled again to −78° C. and 2.77 mL (13.6 mmol, 5 equiv.) of 2-isopropoxy-4,4,5,5-tetramethyl-1,3,2-dioxaborolane was added in one portion via syringe. The reaction was stirred at −78° C. for 1 hour and then allowed to warm to room temperature overnight. The solution was poured into water and extracted with 4×150 mL of methyl tert-butyl ether. The organic layers were combined and washed with 2×150 mL of brine, dried with anhydrous MgSO₄, and filtered. The solvent was removed under vacuum to yield and orange oil, which was purified by column chromatography (5% EtOAc in hexanes) to yield a colorless, viscous oil, 1.34 g (75% yield).

### EXAMPLE 10

### Preparation of Polymer 7

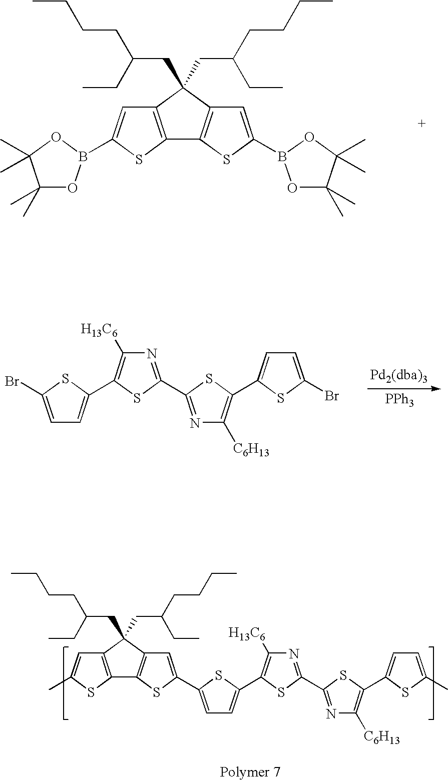

A 100 mL Schlenk flask was charged with 0.1515 g (0.231 mmol) of 2,6-bis(4,4,5,5-tetramethyl-1,3,2-dioxaborolan-2-yl)-4H-4,4-bis(2 ′-ethylhexyl)cyclopenta[2,1-b:3,4-b′]thiophene, 0.152 g (0.231 mmol) of 5,5′-bis(5-bromo-2-thienyl)-4,4′-dihexyl-2,2′-bithiazole, 2.1 mg Pd₂dba₃ (0.00231 mmol), 4.2 mg PPh₃ (0.0162 mmol), and 35 mg (0.0855 mmol) of Aliquat 336. The flask, which was fitted with a condenser, was then evacuated and refilled with argon three times. The reagents were dissolved in a mixture of 20 mL of THF and 15 mL of toluene. 2 mL of a 2M Na₂CO₃ aquesous solution was added to the above solution while stirring. The reaction was heated at 90° C. for 3 days. A 1 mL THF solution of 14 mg (0.1155 mmol) of phenylboronic acid and 1.6 mg (0.00231 mmol) of PdCl₂(PPh₃)₂ was added. Heating was continued for an additional 24 hours. After the reaction was then cooled to 80° C., 10 mL of a 7.5% sodium diethyldithiocarbamate solution in water was added. The mixture was heated at 80° C. with stirring for 18 hours. After the reaction was cooled, the organic layer was separated and washed with warm water (3×100 mL). The toluene solution was concentrated and then poured into 750 mL of stirring MeOH. After the solution was filtered, the dark precipitate was collected and washed with MeOH. The precipitate was then transferred to a Soxhlet thimble and washed with acetone overnight. The product thus obtained was dried under vacuum to give 0.176 g of brown solid (0.195 mmol, 84%). ¹H NMR (200 MHz, CDCl₃): δ 7.2-7.1 (br, 6H), 3.0 (m, 4H), 1.86 (m, 8H), 1.6 (br, 16H), 1.20-0.65 (br, 32H).

### EXAMPLE 11

### Fabrication of Solar Cell

The polymer solar cells were fabricated by doctor-blading a blend of the polymer prepared in Example 3 (PCPDTBT) and PC₆₁BM or PC₇₁BM (purchased from Nano-C, Westwood, Mass.) in a 1:3 w/w ratio sandwiched between a transparent anode and an evaporated metal cathode. The transparent anode was an indium tin oxide (ITO)-covered glass substrate (Merck, Whitehouse Station, N.J.) which was coated with a ˜60 nm thick PEDOT:PSS layer (Baytron PH from H.C. Starck) applied by doctorblading. The ITO-glass-substrate was cleaned by ultrasonification subsequently in acetone, isopropyl alcohol and deionized water. The cathode, a bilayer of a thin (1 nm) LiF layer covered with 80 nm Al, was prepared by thermal evaporation. PCPDTBT and PC₆₁BM or PC₇₁BM were dissolved together in o-dichlorobenzene (ODCB) to give an overall 40 mg/ml solution and was stirred overnight at 60-70° C. inside a glovebox. The active layer thickness, as determined by AFM, was between 150-250 nm. Device characterization was done under AM 1.5 G irradiation (100 mW/cm²) on an Oriel Xenon solar simulator with a well calibrated spectral mismatch of 0.98 jV-characteristics were recorded with a Keithley 2400. Active areas were in the range of 15 to 20 mm². EQE was detected with a lock-in amplifier under monochromatic illumination. Calibration of the incident light was done with a monocrystalline silicon diode. Mobility measurements were done using an Agilent 4155C parameter analyzer. Absorption measurements were done inside the glovebox with an Avantes fiberoptic spectrometer or outside with a HP spectrometer.

The interaction with PCBM and the photoinduced charge transfer was investigated by PL quenching. The PL of pristine PCPDTBT versus PCPDTBT/PCBM composites was measured at liquid N₂ temperatures in a cryostat, excitation was provided by an Ar laser at 488 nm.

Electrochemical experiments were carried out on dropcast polymer films at room temperature in a glovebox. The supporting electrolyte was tetrabutylammonium-hexafluorophosphate (TBAPF₆, electrochemical grade, Aldrich) ˜0.1 M in acetonitrile anhydrous (Aldrich). The working electrode (WE), as well as the counter electrode (CE), was a platinum foil. A silver wire coated with AgCl was used as a reference electrode (RE). After each measurement, the RE was calibrated with ferrocene (E⁰=400 mV vs. NHE) and the potential axis was corrected to NHE (using −4.75 eV for NHE^{24,25}) according to the difference of E⁰ (ferrocene) and the measured E^{1/2} (ferrocene). λₘₐₓ (CHCl₃)=710 nm, λ_{bandedge} (CHCl₃)=780 nm, band gap (CHCl₃)=1.59 eV, λₘₐₓ (film) =700-760 nm, λ_{bandedge} (film)=855 nm, band gap (film)=1.45 eV, HOMO=−5.3 eV, −5.7 eV (electrochem), LUMO=3.85 eV, −4.25 eV, μ₊=2×10⁻² cm₂/Vs (TOF), 1×10⁻³ cm²/Vs (FET).

Other embodiments are in the claims.

What is claimed is:

1. An article, comprising:
first and second window panes; and
a photovoltaic cell between the first and second window panes.

2. The article of claim 1, wherein the photovoltaic cell comprises a first electrode, a second electrode, and an photoactive material disposed between the first and second electrodes, the photoactive material comprising a polymer including a first comonomer repeat unit and a second comonomer repeat unit different from the first comonomer repeat unit, the first comonomer repeat unit comprising a cyclopentadithiophene moiety, a silacyclopentadithiophene moiety, a cyclopentadithiazole moiety, a thiazolothiazole moiety, or a thiazole moiety.

3. The article of claim 2, wherein the first comonomer repeat unit comprises a cyclopentadithiophene moiety.

4. The article of claim 3, wherein the cyclopentadithiophene moiety is substituted with at least one substituent selected from the group consisting of C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl.

5. The article of claim 4, wherein the cyclopentadithiophene moiety is substituted with hexyl, 2-ethylhexyl, or 3,7-dimethyloctyl.

6. The article of claim 4, wherein the cyclopentadithiophene moiety is substituted at 4-position.

7. The article of claim 3, wherein the first comonomer repeat unit comprises a cyclopentadithiophene moiety of formula (1): 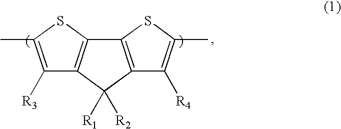
wherein each of R₁, R₂, R₃, and R₄, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀heterocycloalkyl.

8. The article of claim 7, wherein each of R₁ and R₂, independently, is hexyl, 2-ethylhexyl, or 3,7-dimethyloctyl.

9. The article of claim 2, wherein the second comonomer repeat unit comprises a benzothiadiazole moiety, a thiadiazoloquinoxaline moiety, a cyclopentadithiophene oxide moiety, a benzoisothiazole moiety, a benzothiazole moiety, a thiophene oxide moiety, a thienothiophene moiety, a thienothiophene oxide moiety, a dithienothiophene moiety, a dithienothiophene oxide moiety, a tetrahydroisoindole moiety, a fluorene moiety, a silole moiety, a cyclopentadithiophene moiety, a fluorenone moiety, a thiazole moiety, a selenophene moiety, a thiazolothiazole moiety, a cyclopentadithiazole moiety, a naphthothiadiazole moiety, a thienopyrazine moiety, a silacyclopentadithiophene moiety, an oxazole moiety, an imidazole moiety, a pyrimidine moiety, a benzoxazole moiety, or a benzimidazole moiety.

10. The article of claim 9, wherein the second comonomer repeat unit comprises a 3,4-benzo-1,2,5-thiadiazole moiety.

11. The article of claim 9, wherein the second comonomer repeat unit comprises a benzothiadiazole moiety of formula (2), a thiadiazoloquinoxaline moiety of formula (3), a cyclopentadithiophene dioxide moiety of formula (4), a cyclopentadithiophene monoxide moiety of formula (5), a benzoisothiazole moiety of formula (6), a benzothiazole moiety of formula (7), a thiophene dioxide moiety of formula (8), a cyclopentadithiophene dioxide moiety of formula (9), a cyclopentadithiophene tetraoxide moiety of formula (10), a thienothiophene moiety of formula (11), a thienothiophene tetraoxide moiety of formula (12), a dithienothiophene moiety of formula (13), a dithienothiophene dioxide moiety of formula (14), a dithienothiophene tetraoxide moiety of formula (15), a tetrahydroisoindole moiety of formula (16), a thienothiophene dioxide moiety of formula (17), a dithienothiophene dioxide moiety of formula (18), a fluorene moiety of formula (19), a silole moiety of formula (20), a cyclopentadithiophene moiety of formula (21), a fluorenone moiety of formula (22), a thiazole moiety of formula (23), a selenophene moiety of formula (24), a thiazolothiazole moiety of formula (25), a cyclopentadithiazole moiety of formula (26), a naphthothiadiazole moiety of formula (27), a thienopyrazine moiety of formula (28), a silacyclopentadithiophene moiety of formula (29), an oxazole moiety of formula (30), an imidazole moiety of formula (31), a pyrimidine moiety of formula (32), a benzoxazole moiety of formula (33), or a benzimidazole moiety of formula (34): 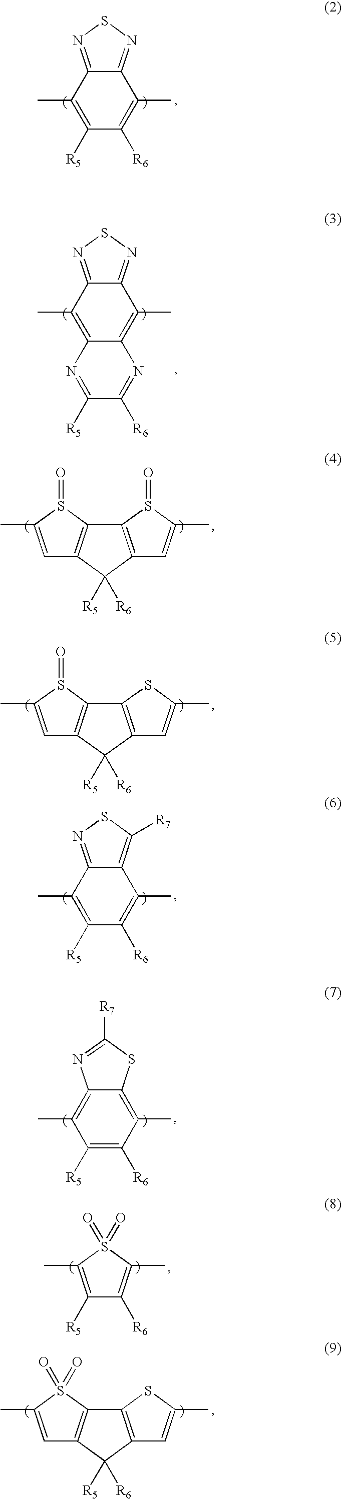 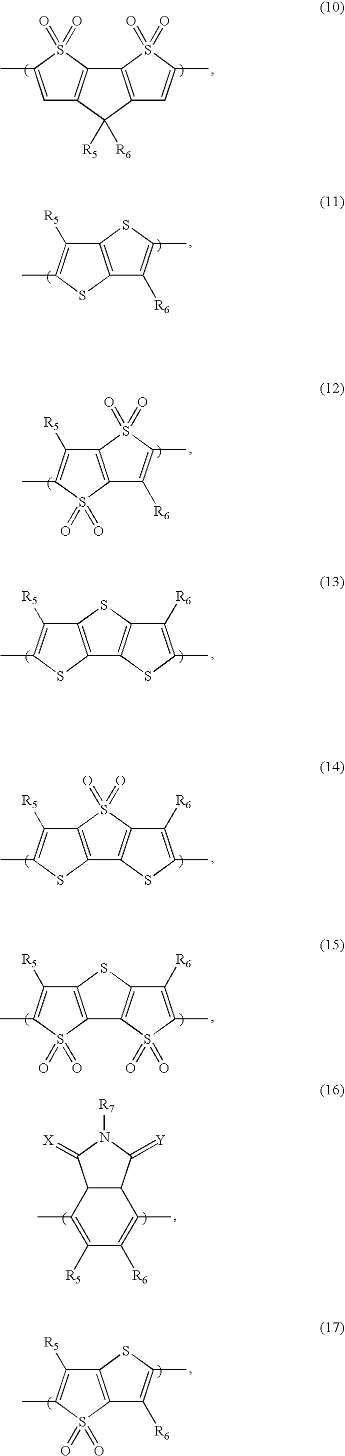 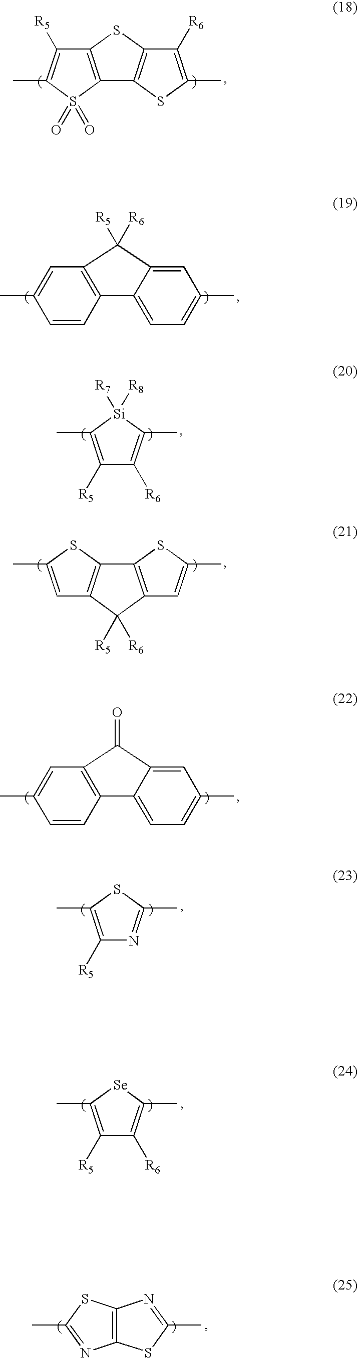 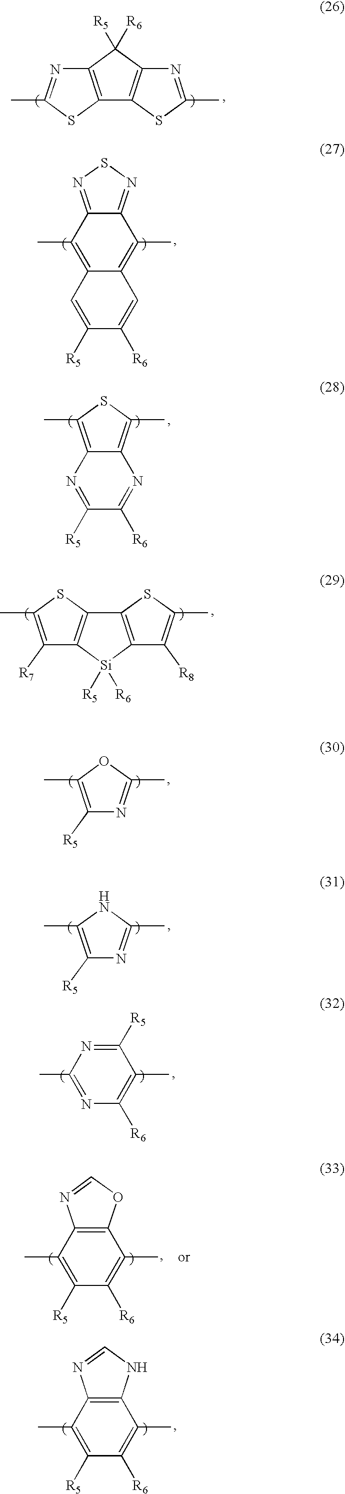
wherein
each of X and Y, independently, is CH₂, O, or S;
each of R₅ and R₆, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R, in which R is H, C₁-C₂₀ alkyl, C₁-C₂₀ alkoxy, aryl, heteroaryl, C₃-C₂₀ cycloalkyl, or C₁-C₂₀heterocycloalkyl; and
each of R₇ and R₈, independently, is H, C₁-C₂₀ alkyl, C₁-C₂₀ alkoxy, aryl, heteroaryl, C₃-C₂₀ cycloalkyl, or C₃-C₂₀ heterocycloalkyl.

12. The article of claim 11, wherein the second comonomer repeat unit comprises a benzothiadiazole moiety of formula (2).

13. The article of claim 12, wherein each of R₁ and R₂ is H.

14. The article of claim 2, wherein the second comonomer repeat unit comprises at least three thiophene moieties.

15. The article of claim 14, wherein at least one of the thiophene moieties is substituted with at least one substituent selected from the group consisting of C₁-C₂₀ alkyl, C₁-C₂₀ alkoxy, aryl, heteroaryl, C₃-C₂₀ cycloalkyl, and C₃-C₂₀ heterocycloalkyl.

16. The article of claim 14, wherein the second comonomer repeat unit comprises five thiophene moieties.

17. The article of claim 2, wherein the polymer further comprises a third comonomer repeat unit, the third comonomer repeat unit comprising a thiophene moiety or a fluorene moiety.

18. The article of claim 17, wherein the thiophene or fluorene moiety is substituted with at least one substituent selected from the group consisting of C₁-C₂₀ alkyl, C₁-C₂₀ alkoxy, aryl, heteroaryl, C₃-C₂₀ cycloalkyl, and C₃-C₂₀ heterocycloalkyl.

19. The article of claim 2, wherein the photoactive material further comprises an electron acceptor material.

20. The article of claim 19, wherein the electron acceptor material comprises a fullerene.

21. The article of claim 20, wherein the electron acceptor material comprises PCBM.

22. The article of claim 19, wherein the polymer and the electron acceptor material each has a LUMO energy level, the LUMO energy level of the polymer is at least about 0.2 eV less negative than the LUMO energy level of the electron acceptor material.

23. The article of claim 1, wherein the photovoltaic cell is disposed on a surface of a window blind between first and second window panes.

24. The article of claim 23, wherein the window blind is foldable or rollable.

25. An article, comprising:
a window blind;
a photovoltaic cell on a surface of a window blind.

26. The article of claim 25, wherein the window blind is foldable or rollable.
